(19) United States
(12) Patent Application Publication
(10) Pub. No.: US 2021/0376136 A1
(43) Pub. Date: Dec. 2, 2021

(54) NITRIDE SEMICONDUCTOR DEVICE

(71) Applicant: ROHM Co., Ltd., Kyoto (JP)

(72) Inventor: MINORU AKUTSU, KYOTO (JP)

(21) Appl. No.: 17/328,956

(22) Filed: May 24, 2021

(30) Foreign Application Priority Data
May 27, 2020 (JP) 2020-092311

(51) Int. Cl. H01L 29/778; H01L 29/20; H01L 29/205; H01L 29/207; H01L 29/417; H01L 21/306; H01L 29/40; H01L 29/66

(52) U.S. Cl. CPC H01L 29/7786; H01L 29/2003; H01L 29/205; H01L 29/66462; H01L 29/4175; H01L 21/30621; H01L 29/401; H01L 29/207

(57) ABSTRACT

The present disclosure provides a nitride semiconductor device capable of reducing the ohmic contact resistance of a source electrode and a drain electrode with respect to a two-dimensional electron gas. The nitride semiconductor device includes: a first nitride semiconductor layer configured as an electron transportation layer, a second nitride semiconductor layer formed on the first nitride semiconductor layer and configured as an electron supply layer, an etch stop layer formed on the second nitride semiconductor layer and formed by a nitride semiconductor material having a bandgap greater than that of the second nitride semiconductor layer, a gate formed on the etch stop layer; and a source electrode and a drain electrode, disposed above the etch stop layer on opposite sides, wherein the gate is between the source electrode and the drain electrode. Lower portions of the source electrode and the drain electrode penetrate the etch stop layer into a middle portion of the second semiconductor layer along a vertical direction.

### BACKGROUND

### Field of the Disclosure

The present disclosure relates to a nitride semiconductor dev ice including a group III nitride semiconductor (hereinafter, sometimes simply referred to as “nitride semiconductor”).

### Description of the Prior Art

The so-called group III nitride semiconductor refers to a semiconductor in which nitrogen is used as a group V element among group III-V semiconductors. Examples includes aluminum nitride (AlN), gallium nitride (GaN), and indium nitride (InN). Generally, it can be represented as AlₓIn_{y}Ga_{1-x-y}N (0≤x≤1, 0≤y≤1, 0≤x+y≤1).

A HEMT(High Electron Mobility Transistor) using such a nitride semiconductor has been proposed. Such a HEMT includes, for example, an electron transportation layer made of GaN: and an electron supply layer made of AlGaN epitaxially grown on the electron transportation layer. A pair of source electrode and drain electrode are formed in contact with the electron supply layer, and a gale electrode is arranged therebetween.

Due to the polarization caused by the lattice mismatch between GaN and AlGaN, a two-dimensional electron gas is formed in the electron transportation layer only a few Å inside from the interface between live electron transportation layer and the electron supply layer. The two-dimensional electron gas is used as a channel to connect the source and drain. If the two-dimensional electron gas is blocked by applying a control voltage to the gate electrode, the source and drain are blocked. In a state where the control voltage is not applied to the gate electrode, the source and the drain are electrically connected, so that it becomes a normally-on device.

Devices using nitride semiconductors have characteristics such as high withstand voltage, high-temperature operation, large current density, high-speed switching, and low on-resistance. Therefore, applications to power devices are proposed in Patent Document 1, for example.

Patent Document 1 discloses a structure in which a ridge-shaped p-type GaN gate layer (nitride semiconductor gate layer) is laminated on an AlGaN electron supply layer, and a gate electrode is disposed thereon. The extended depletion layer of the p-type GaN gate layer makes the channel disappear to achieve normally-off.

Patent Document 2 discloses a nitride semiconductor device including an electron transportation layer (GaN channel layer), an electron supply layer (AlGaN barrier layer) formed on the electron transportation layer, and ohmic electrodes (source electrode and drain electrode). The lower end of the ohmic electrode penetrates the electron supply layer and stops at the middle portion of the thickness of the electron transportation layer. The ohmic electrode penetrates the two-dimensional electron gas in the electron supply layer.

In the semiconductor device described in Patent Document 2, no two-dimensional electron gas is generated below the lower end of the ohmic electrode. In addition, in the semiconductor device described in Patent Document 2, the ohmic electrode is electrically connected to the two-dimensional electron gas only in a portion in contact with the two-dimensional electron gas on its side surface.

### PRIOR ART LITERATURE

### Patent Literature

[Patent Document 1] Japanese Patent Publication No. 2017-73506

[Patent Document 2] Japanese Patent Publication No. 2011-129769

### SUMMARY

### Problems to be Solved

An object of the present disclosure is to provide a nitride semiconductor device capable of reducing the ohmic contact resistance of the source electrode and the drain electrode with respect to the two-dimensional electron gas and a manufacturing method thereof.

### Technical Means for Solving the Problems

One embodiment of the present disclosure provides a nitride semiconductor device, which includes: a first nitride semiconductor layer configured as an electron transportation layer; a second nitride semiconductor layer over the first nitride semiconductor layer and configured as an electron supply layer, wherein the second nitride semiconductor layer has a bandgap greater than a bandgap of the first nitride semiconductor layer; an etch stop layer over the second nitride semiconductor layer, including a nitride semiconductor material having a bandgap greater than the second nitride semiconductor layer; a gate, over the etch stop layer; and a source electrode and a drain electrode over the etch stop layer, wherein the gate is between the source electrode and the drain electrode, wherein the gate includes: a third nitride semiconductor layer over the second nitride semiconductor layer, wherein the third nitride semiconductor layer is ridge-shaped and includes acceptor impurity; and a gate electrode over the third nitride semiconductor layer, wherein lower portions of the source electrode and the drain electrode penetrate the etch stop layer and extend into a middle portion of the second semiconductor layer along a vertical direction.

In the configuration, the ohmic contact resistance of the source electrode and the drain electrode with respect to the two-dimensional electron gas can be reduced.

In one embodiment of the present disclosure, a distance between a lower surface of the second nitride semiconductor layer and the lower portions of the source electrode and the drain electrode is in a range from one fifth of a thickness of the second nitride semiconductor layer to a half of the thickness of the second nitride semiconductor layer.

One embodiment of the present disclosure provides a nitride semiconductor device, which includes: a first nitride semiconductor layer configured as an electron transportation layer; a second nitride semiconductor layer over the first nitride semiconductor layer and configured as an electron supply layer, wherein the second nitride semiconductor layer has a bandgap greater than a bandgap of the first nitride semiconductor layer; an etch stop layer over the second nitride semiconductor layer, including a nitride semiconductor material having a bandgap greater than the second nitride semiconductor layer; a gate over the etch stop layer, and a source electrode and a drain electrode over the etch stop layer, wherein the gate is between the source electrode and the drain electrode, wherein the gate includes: a third nitride semiconductor layer over the second nitride semiconductor layer, wherein the third nitride semiconductor layer is ridge-shaped and includes acceptor impurity; and a gate electrode over the third nitride semiconductor layer, wherein lower portions of the source electrode and the drain electrode penetrate the etch stop layer along a vertical direction and is in direct contact with an upper surface of the second semiconductor layer.

In the configuration, the ohmic contact resistance of the source electrode and the drain electrode with respect to the two-dimensional electron gas can be reduced.

In one embodiment of the present disclosure, a thickness of the etch stop layer is in a range from 0.5 nm to 2 nm.

In one embodiment of the present disclosure, the etch stop layer and the second nitride semiconductor layer include aluminum, and a concentration of aluminum in the etch stop layer is greater than a concentration of aluminum in the second nitride semiconductor layer.

In one embodiment of the present disclosure, the concentration of aluminum in the etch stop layer is greater than 80%.

In one embodiment of the present disclosure, the concentration of aluminum in the second nitride semiconductor layer is less than 25%.

In one embodiment of the present disclosure, a difference between the concentration of aluminum in the etch stop layer and the concentration of aluminum in the second nitride semiconductor layer is greater than 50%.

In one embodiment of the present disclosure, the etch stop layer is made of AlGaN or AlN.

One embodiment of the present disclosure provides a nitride semiconductor device, which includes: a first nitride semiconductor layer configured as an electron transportation layer; a second nitride semiconductor layer over the first nitride semiconductor layer and configured as an electron supply layer, wherein the second nitride semiconductor layer has a bandgap greater than a bandgap of the first nitride semiconductor layer; a gate over the second nitride semiconductor layer; and a source electrode and a drain electrode over the second nitride semiconductor layer, wherein the gate is between the source electrode and the drain electrode, wherein the gate includes: a third nitride semiconductor layer over the second nitride semiconductor layer, wherein the third nitride semiconductor layer is ridge-shaped and includes acceptor impurity; and a gate electrode over the third nitride semiconductor layer, wherein lower portions of the source electrode and the drain electrode extend from an upper surface of the second semiconductor layer and into a middle portion of the second semiconductor layer along a vertical direction.

In the configuration, the ohmic contact resistance of the source electrode and the drain electrode with respect to the two-dimensional electron gas can be reduced.

In one embodiment of the present disclosure, a distance between a lower surface of the second nitride semiconductor layer and the lower portions of the source electrode and the drain electrode is in a range from one fifth of a thickness of the second nitride semiconductor layer to a half of the thickness of the second nitride semiconductor layer.

In one embodiment of the present disclosure, a thickness of the third nitride semiconductor layer is greater than 110 nm.

In one embodiment of the present disclosure, the first nitride semiconductor layer is made of GaN; the second nitride semiconductor layer is made of AlGaN; and the third nitride semiconductor layer is made of AlGaN.

In one embodiment of the present disclosure, the acceptor impurity is Magnesium or Zinc.

One embodiment of the present disclosure provides a method tor forming a nitride semiconductor device, which includes; forming a first nitride semiconductor layer configured as an electron transportation layer over a substrate; forming a second nitride semiconductor layer configured as an electron supply layer over the substrate subsequent to forming the first nitride semiconductor layer; forming an etch stop layer over the substrate subsequent to forming the second nitride semiconductor layer; forming a semiconductor gate material film made of a nitride semiconductor including acceptor impurity over the substrate after forming the etch stop layer; forming a gate electrode Hint over the semiconductor gate material film; selectively etching the gate electrode film to form a gate electrode over the semiconductor gate material film; selectively etching the semiconductor gate material film to form a semiconductor gate layer over the etch stop layer, wherein a semiconductor gate layer is formed above the gate electrode; forming a passivation film over the etch stop layer, wherein the passivation film covers an exposed surface of the second nitride semiconductor layer, the semiconductor gate layer, and an exposed surface of the gate electrode; forming contact holes in a film stack of the passivation layer, the etch stop layer, and the second nitride semiconductor layer, including: forming a source contact hole and a drain contact hole penetrating the passivation film and the etch stop layer along a vertical direction and stopping at a middle portion of the second nitride semiconductor layer; and forming a source electrode and a drain electrode respectively traversing the source contact hole and the drain contact hole, wherein the source electrode and the drain electrode are in direct contact with the second nitride semiconductor layer.

In one embodiment of the present disclosure, forming contact holes includes: performing a dry etching operation by using fluorine-containing gas to form a first hole penetrating the passivation layer; and performing a dry itching operation by using chlorine-containing gas to form a second hole connecting to the first hole, penetrating the etch stop layer and stopping at the middle portion of the second nitride semiconductor layer.

One embodiment of the present disclosure provides a method for forming a nitride semiconductor device, which includes: forming a first nitride semiconductor layer configured as an electron transportation layer over a substrate; forming a second nitride semiconductor layer con figured as an electron supply layer over the substrate subsequent to forming the first nitride semiconductor layer; forming an etch stop layer over the substrate subsequent to forming the second nitride semiconductor layer; forming a semiconductor gate material film made of a nitride semiconductor including acceptor impurity over the substrate after forming the etch stop layer; forming a gate electrode film over the semiconductor gate material film; selectively etching the gate electrode film to form a gate electrode over the semiconductor gate material film; selectively etching the semiconductor gate material film to form a semiconductor gate layer over the etch stop layer, wherein a semiconductor gate layer is formed above the gate electrode; forming a passivation film over the second nitride semiconductor layer, wherein the passivation film covers an exposed surface of the second nitride semiconductor layer, the semiconductor gate layer, and an exposed surface of the gate electrode; forming contact holes in a film stack of the passivation layer and the etch stop layer, including: forming a source contact hole and a drain contact hole penetrating the passivation film and the etch stop layer along a vertical direction and stopping at an upper surface of the second nitride semiconductor layer; and forming a source electrode and a drain electrode respectively traversing the source contact hole and the drain contact hole, wherein the source electrode and the drain electrode are in direct contact with the upper surface of the second nitride semiconductor layer.

In one embodiment of the present disclosure, forming contact holes includes: performing a dry etching operation by using fluorine-containing gas to form a first hole penetrating the passivation layer; performing a dry treatment by using oxygen-containing gas to oxidize a region in the passivation layer proximal to the first hole; and performing a wet etching operation to remove the region oxidized by the dry treatment, thereby forming a second hole connecting to the first hole, penetrating the etch stop layer and stopping at an upper surface of the second nitride semiconductor layer.

One embodiment of the present disclosure provides a method tor forming a nitride semiconductor device, which includes: forming a first nitride semiconductor layer configured as an electron transportation layer over a substrate; forming a second nitride semiconductor layer configured as an electron supply layer over the substrate subsequent to forming the first nitride semiconductor layer; forming a semiconductor gate material film made of a nitride semiconductor including acceptor impurity over the substrate after forming the second nitride semiconductor layer; forming a gate electrode film over the semiconductor gate material film; selectively etching the gate electrode film to form a gate electrode over the semiconductor gate material film; selectively etching the semiconductor gate material film to form a semiconductor gate layer over the second nitride semiconductor layer, wherein a semiconductor gate layer is formed above the gate electrode; forming a passivation film over the second nitride semiconductor layer, wherein the passivation film covers an exposed surface of the second nitride semiconductor layer, the semiconductor gate layer, and an exposed surface of the gate electrode; forming contact holes in a film stack of the passivation layer and the second nitride semiconductor layer, including: forming a source contact hole and a drain contact hole penetrating the passivation film along a vertical direction and stopping at a middle portion of the second nitride semiconductor layer; and forming a source electrode and a drain electrode respectively traversing the source contact hole and the drain contact hole, wherein the source electrode and the drain electrode are in direct contact with the second nitride semiconductor layer.

In one embodiment of the present disclosure, forming contact holes includes: performing a dry etching operation by using fluorine-containing gas to form a first hole penetrating the passivation layer; and performing a dry etching operation by utilizing chlorine-containing gas to form a second hole connecting to the first hole, penetrating the etch stop layer and stopping at the middle portion of the second nitride semiconductor layer.

### BRIEF DESCRIPTION OF THE DRAWINGS

FIG. 1 is a cross-sectional view illustrating the structure of a nitride semiconductor device according to a first embodiment of the present disclosure;

FIG. 2A is a cross-sectional view showing an example of a manufacturing operation of the nitride semiconductor device of FIG. 1, according to some embodiments of the present disclosure;

FIG. 2B is a cross-sectional view illustrating the next operation of FIG. 2A, according to some embodiments of the present disclosure;

FIG. 2C is a cross-sectional view illustrating the next operation of FIG. 2B, according to some embodiments of the present disclosure;

FIG. 2D is a cross-sectional view illustrating the next operation of FIG. 2C, according to some embodiments of the present disclosure;

FIG. 2E is a cross-sectional view illustrating the next operation of FIG. 2D, according to some embodiments of the present disclosure;

FIG. 2F is a cross-sectional view illustrating the next operation of FIG. 2E, according to some embodiments of the present disclosure;

FIG. 2G is a cross-sectional view illustrating the next operation of FIG. 2F, according to some embodiments of the present disclosure;

FIG. 2H is a cross-sectional view illustrating the next operation of FIG. 2G, according to some embodiments of the present disclosure;

FIG. 2I is a cross-sectional view illustrating the next operation of FIG. 2H, according to some embodiments of the present disclosure;

FIG. 2J is a cross-sectional view illustrating the next operation of FIG. 2I, according to some embodiments of the present disclosure;

FIG. 2K is a cross-sectional view illustrating the next operation of FIG. 2J, according to some embodiments of the present disclosure;

FIG. 3 is a cross-sectional view illustrating the structure of a nitride semiconductor device according to a second embodiment of the present disclosure;

FIG. 4A is a cross-sectional view illustrating an example of a manufacturing process of the nitride semiconductor device of FIG. 3, according to some embodiments of the present disclosure;

FIG. 4B is a cross-sectional view illustrating the next process of FIG. 4A, according to some embodiments of the present disclosure;

FIG. 40 is a cross-sectional view illustrating the next process of FIG. 4B, according to some embodiments of the present disclosure;

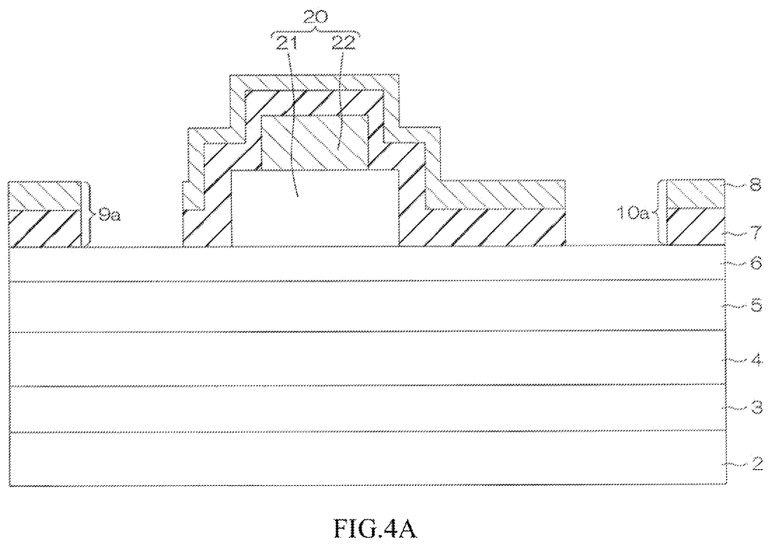

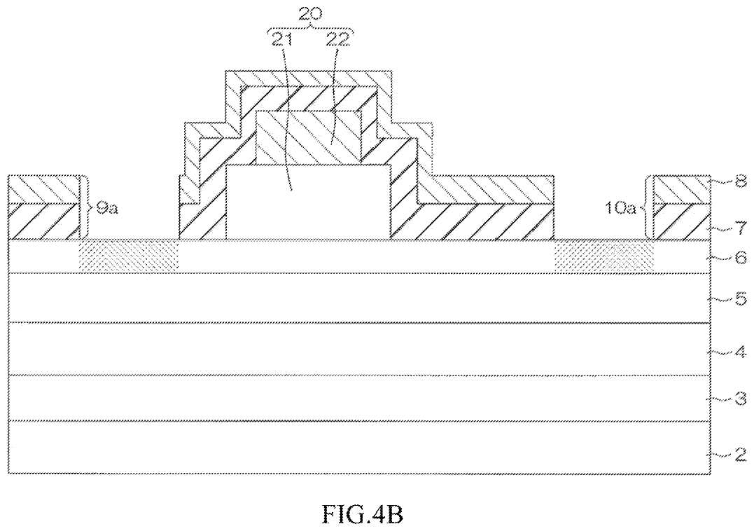

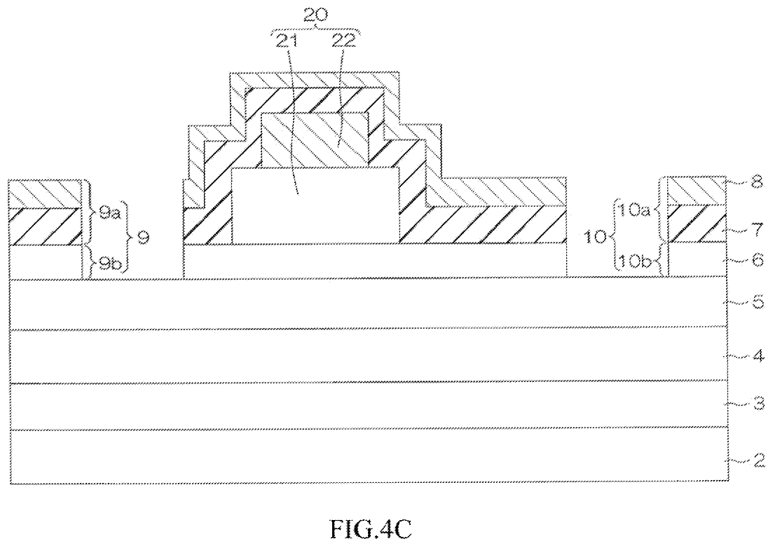

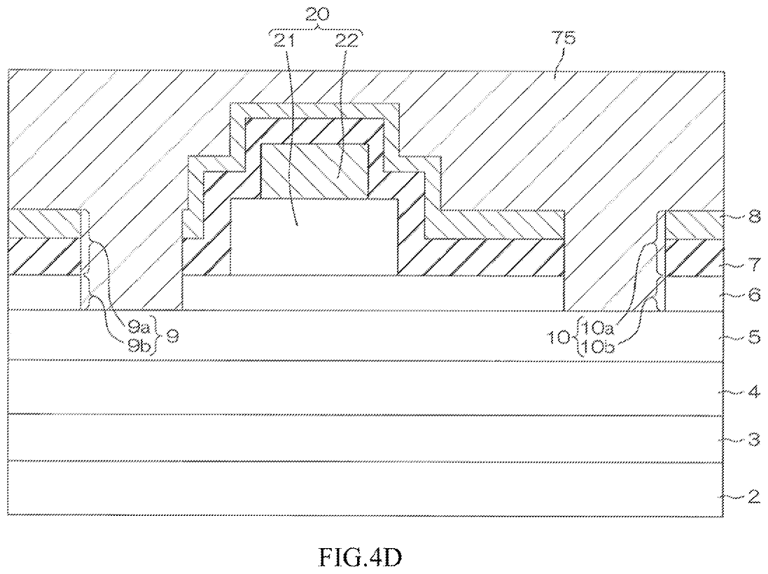

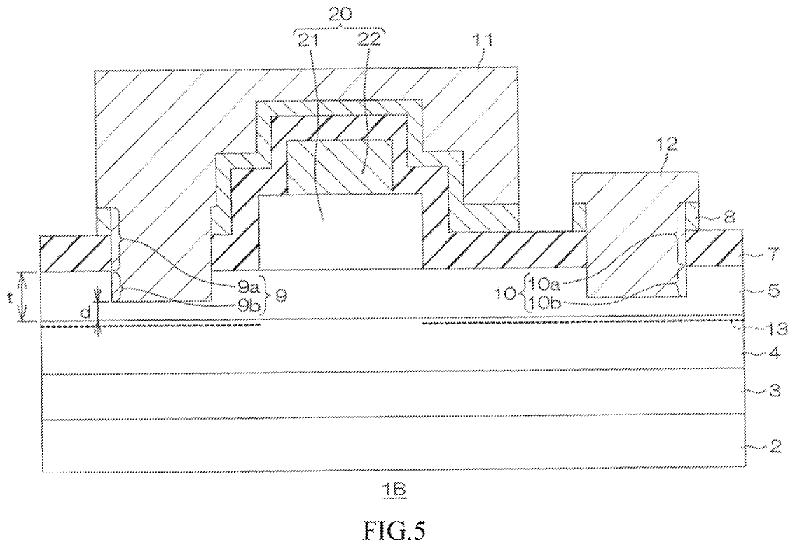

FIG. 4D is a cross-sectional view illustrating the next process of FIG. 4C, according to some embodiments of the present disclosure; and

FIG. 5 is a cross-sectional view illustrating the structure of a nitride semiconductor device according to a third embodiment of the present disclosure.

### DETAILED DESCRIPTION OF THE EMBODIMENTS

Hereinafter, embodiments of the present disclosure will be described in detail with reference to the accompanying drawings.

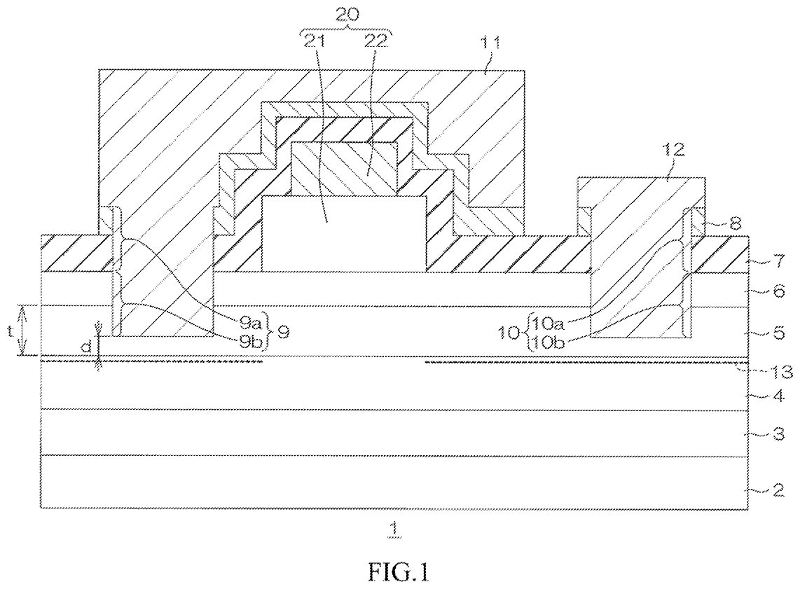

FIG. 1 is a cross-sectional view illustrating the structure of a nitride semiconductor device according to a first embodiment of the present disclosure.

The nitride semiconductor device 1 includes a substrate 2, a buffer layer 3 formed above a surface of the substrate 2, a first nitride semiconductor layer 4 epitaxially grown above the buffer layer 3, and a second nitride semiconductor layer 5 epitaxially grown above the first nitride semiconductor layer 4. Furthermore, the nitride semiconductor device 1 includes an etch stop layer 6 epitaxially grown above the second nitride semiconductor layer 5, and a gale 20 formed above the etch stop layer 6.

Furthermore, the nitride semiconductor device 1 includes a passivation film 7 covering the etch stop layer 6 and the gate 20, and a harrier metal film 8 formed above the passivation film 7. Furthermore, the nitride semiconductor device 1 includes a source electrode 11 and a drain electrode 12 in contact with the second nitride semiconductor layer 5 respectively via a source contact hole 9 and a drain contact hole 10 formed in a laminated film of the second nitride semiconductor layer 5, the etch stop layer 6, the passivation film 7, and the barrier metal film 8. The source electrode 11 is apart from the drain electrode 12 by an interval. The source electrode 11 is configured to cover the gate 20.

The substrate 2 may also be a low-resistance silicon substrate, for example. The low-resistance silicon substrate may be, for example, a p-type substrate having a resistivity of 0.001 Ωmm to 0.5 Ωmm (more specifically, about 0.01 Ωmm to 0.1 Ωmm). In addition, the substrate 2 may be a low-resistance SiC substrate, a low-resistance GaN substrate, or the like, in addition to the low-resistance silicon substrate. The substrate 2 has a thickness of, for example, about 650 μm in the semiconductor fabrication operation, and is ground to about 300 μm or less in the pre-chip formation stage. The substrate 2 is electrically connected to the source electrode 11.

In this embodiment, the buffer layer 3 includes a multilayer buffer layer in which a plurality of nitride semiconductor films is laminated. In this embodiment, the buffer layer 3 includes: a first buffer layer (not shown), which is in contact with the surface of the substrate 2 and is made of an AlN film; and a second buffer layer (not shown), which is laminated on the surface of the first buffer layer (the surface on the side opposite to the substrate 2) and includes an AlN/AlGaN superlattice layer. The film thickness of the first buffer layer is about 100 nm to 500 nm. The film thickness of the second buffer layer is about 500 nm to 2 μm. The buffer layer 3 may also include a single film or a composite film of AlGaN or an AlGaN/GaN superlattice film, for example.

The first nitride semiconductor layer 4 constitutes an electron transportation layer. In this embodiment, the first nitride semiconductor layer 4 is composed of a GaN layer, and its thickness is about 0.5 μm to 2 μm. In addition, in order to reduce the leakage current flowing through the first nitride semiconductor layer 4, semi-insulating impurities may be introduced into the outside of the surface region. In such a circumstance, the concentration of impurities is preferably 4×10¹⁶ cm⁻³ or more. In addition, the impurity is, for example, C or Fe.

The second nitride semiconductor layer 5 constitutes an electron supply layer. The second nitride semiconductor layer 5 is made of a nitride semiconductor having a band gap larger than that of the first nitride semiconductor layer 4. Specifically, the second nitride semiconductor layer 5 is made of a nitride semiconductor having a concentration of aluminum higher than that of the first nitride semiconductor layer 4. In nitride semiconductors, the higher the concentration of aluminum is, the larger the band gap is. In this embodiment, the second nitride semiconductor layer 5 is composed of an AlₓGa₁₋ₓN layer (0<x≤1). The concentration of aluminum of the second nitride semiconductor layer 5 is preferably 25% or less. That is, x is preferably 0.25 or less. Specifically, x is preferably 0.1 to 0.25, more preferably 0.1 to 0.15. The thickness of the second nitride semiconductor layer 5 is preferably X nm to 20 nm.

In this way, the first nitride semiconductor layer (electron transportation layer) 4 and the second nitride semiconductor layer (electron supply layer) 5 are composed of nitride semiconductors with different band gaps (which is related to concentration of aluminum), and a lattice mismatch occurs therebetween. In addition, due to the spontaneous polarization of the first nitride semiconductor layer 4 and the second nitride semiconductor layer 5, as well as the piezoelectric polarization caused by the lattice mismatch between them, the energy level of the conduction band of the first nitride semiconductor layer 4 in the interface between the first nitride semiconductor layer 4 and the second nitride semiconductor layer 5 is lower than the Fermi level. Thus, at a position in the first nitride semiconductor layer 4 and proximal to the interface between the first nitride semiconductor layer 4 and the second nitride semiconductor layer 5 (for example, at a distance of about several Å from the interface), a two-dimensional electron gas (2DEG) 13 expands.

The etch stop layer 6 is a layer configured to prevent the surface of the second nitride semiconductor layer 5 from being shaved off during the formation of the third nitride semiconductor layer 21 having the ridge shape (which will be subsequently discussed)by etching. The etch stop layer 6 is made of a nitride semiconductor having a band gap larger than that of the second nitride semiconductor layer 5. Specifically, the etch stop layer 6 is made of a nitride semiconductor having a concentration of aluminum greater than that of the second nitride semiconductor layer 5.

In this embodiment, the etch stop layer 6 is composed of an Al_{z}Ga_{1-z}N layer (0<z≤1, z>x). In order to have the etch stop layer 6 functioning as an etch stop layer, it is preferable that the concentration of aluminum of the etch stop layer 6 is greater than that of the second nitride semiconductor layer 5. That is, it is preferable that z is greater than x. The concentration of aluminum of the etch stop layer 6 is preferably 80% or more. That is, z is preferably 0.8 or more. In addition, the difference between the concentration of aluminum of the etch stop layer 6 and the second nitride semiconductor layer 5 is preferably 50% or more, in which the concentration of aluminum of the second nitride semiconductor layer 5 is lower than that of the etch stop layer 6. Moreover, the etch stop layer 6 may also include an AlN layer.

The thickness of the etch stop layer 6 is preferably 0.5 nm or more and 2 nm or less. The criticality of why it is preferably 0.5 or more is that for the etch stop layer 6 to function as an etch stop layer, it may be necessary to have the thickness being 0.5 nm or more. The criticality of why it is preferably 2 nm or less is that if the thickness of the etch stop layer 6 is more than 2 nm, the density of the two-dimensional electron gas 13 formed in the first nitride semiconductor layer 4 increases due to the influence of the etch stop layer 6, and the threshold voltage may be reduced.

The gate 20 includes a ridge-shaped third nitride semiconductor layer (semiconductor gate layer) 21 epitaxially grown on the etch stop layer 6 and a gate electrode 22 formed on the third nitride semiconductor layer 21. The gate 20 is arranged between the source contact hole 9 and the drain contact hole 10 and may be relatively closer to the source contact hole 9.

The third nitride semiconductor layer 21 is made of a nitride semiconductor doped with acceptor type impurities. More specifically, the third nitride semiconductor layer 21 is composed of an Al_{y}Ga_{1-y}N (0≤y<1, y<x) layer doped with acceptor-type impurities. In this embodiment, the third nitride semiconductor layer 21 is composed of a GaN layer (p-type GaN layer) doped with acceptor type impurities. In this embodiment, the cross section of the third nitride semiconductor layer 21 is rectangular.

The third nitride semiconductor layer 21 is con figured to alter the conduction band at the interface between the first nitride semiconductor layer 4 (electron transportation layer) and the second nitride semiconductor layer 5 (electron supply layer), preventing the generation of the two-dimensional electron gas 13 in the region directly below the gate 20 in a state when the gate voltage is not applied.

In this embodiment, the acceptor type impurity is Mg (magnesium). The acceptor type impurities may be acceptor-type impurities other than Mg, such as Zn (zinc).

The film thickness of the third nitride semiconductor layer 21 is in a range from about 60 nm to about 200 nm. The film thickness of the third nitride semiconductor layer 21 is preferably greater than 100 nm, and more preferably 110 nm or more. The film thickness of the third nitride semiconductor layer 21 is more preferably 110 nm or more and 150 nm or less. The reason is that when the film thickness of the third nitride semiconductor layer 21 is 110 nm or more and 150 nm or less, the maximum rated voltage of the gate in the positive direction can be increased. In this embodiment, the film thickness of the third nitride semiconductor layer 21 is about 120 nm.

The cross section of the gate electrode 22 is rectangular. The width of the gate electrode 22 is narrower than the width of the third nitride semiconductor layer 21. The gate electrode 22 is formed over the middle portion along width direction of the upper surface of the third nitride semiconductor layer 21. Therefore, a step is formed between the upper surface of the gate electrode 22 and the upper surface of one side of the third nitride semiconductor layer 21, and a step is formed between the upper surface of the gate electrode 22 and the upper surface of another side of the third nitride semiconductor layer 21. In addition, in a plan view, the two opposite side edges of the gate electrode 22 are more inward than the corresponding side edges of the third nitride semiconductor layer 21.

In this embodiment, the gate electrode 22 is in Schottky contact with the upper surface of the third nitride semiconductor layer 21. The gate electrode 22 is made of TiN. The film thickness of the gate electrode 22 is in a range from about 60 nm to about 200 nm. The gate electrode 22 may include any single film of a Ti film, a TiN film, or a TiW film, or a composite film composed of any combination of two or more of the aforementioned films.

The passivation film 7 covers the surface of the etch stop layer 6 (except for the area w here the contact holes 9 and 10 face) and the sides and top surface of the gate 20. The thickness of the passivation film 7 is in a range from about 50 nm to about 200 nm. In this embodiment, the passivation film 7 is composed of a SiN film. The passivation film 7 may alternatively include any single film of a SiN film, a SiO₂ film, a SiON film, an Al₂O₃ film, an AlN film, or an AlON film, or a composite film composed of any combination of two or more of the aforementioned films.

A barrier metal film 8 is selectively formed above the passivation film 7. In this embodiment, the barrier metal film 8 is composed of a TiN film, and its thickness is about 50 nm. The barrier metal film 8 is configured to obstruct the metal materials constituting the source electrode 11 and the drain electrode 12 from diffusing into the passivation film 7.

The source contact hole 9 includes a first portion 9a that penetrates the laminated film of the barrier metal film 8 and the passivation film 7 along the vertical direction, and a second portion 9b that connects with the first portion 9a and extends through the etch stop layer 6 to the middle portion of the second nitride semiconductor layer 5 along the vertical direction.

The end portion on the ohmic contact side of the source electrode 11 (the lower end portion of the source electrode 11) is embedded in the source contact hole. Accordingly, the end portion on the ohmic contact side of the source electrode 11 penetrates the laminated film of the barrier metal film 8, the passivation film 7 and the etch stop layer 6 along the vertical direction, and extends into the middle portion of the second nitride semiconductor layer 5 along the vertical direction. That is, the lower end of the end portion on the ohmic contact side of the source electrode 11 stops at the middle portion of the second nitride semiconductor layer 5 along the vertical direction.

Similarly, the drain contact hole 10 includes a first portion 10a that penetrates the laminated film of the barrier metal film 8 and the passivation film 7 along the vertical direction, and a second portion 10b that connects with the first portion 10a and extends through the etch stop layer 6 to the middle portion of the second nitride semiconductor layer 5 along the vertical direction.

The parts of the first portions 9a and 10a that penetrate the passivation film 7 is equivalent to “the first hole” of the present disclosure corresponding to the first embodiment, and the second portions 9a and 10a are equivalent to the “the second hole” of the present disclosure corresponding to the first embodiment.

The end portion on the ohmic contact side of the drain electrode 12 (the lower end portion of the drain electrode 12) is embedded in the drain contact hole 10. Accordingly, the end portion on the ohmic contact side of the drain electrode 12 penetrates the laminated film of the barrier metal film 8, the passivation film 7, and the etch stop layer 6 along the vertical direction and extends into the middle portion of the second nitride semiconductor layer 5 along the vertical direction. That is, the lower end of the end portion on the ohmic contact side of the drain electrode 12 stops at the middle portion of the second nitride semiconductor layer 5 along the vertical direction.

The depth level of the bottom surfaces of the second portions 9a and 10a of the source contact hole 9 and the drain contact hole 10 are approximately identical. The distance d between the bottom surfaces of the second portions 9a and 10a (the lower ends of the source electrode 11 and the drain electrode 12) and the lower surface of the second nitride semiconductor layer 5 is preferably more than ⅕ and less than ½ of the film thickness t of the second nitride semiconductor layer 5.

The reason lies in that if d is less than ⅕ of t, it is difficult to form the two-dimensional electron gas 13 under the lower ends of the source electrode 11 and the drain electrode 12. On the other hand, the reason is that if d is greater than ½ of t, the ohmic contact resistance of the source electrode 11 and the drain electrode 12 to the two-dimensional electron gas 13 increases. In this embodiment, d is about ¼ of t. For example, when t is in a range front about 8 nm to about 20 nm, then d can be in a range from about 2 nm to about 5 nm.

The source electrode 11 and the drain electrode 12 include, for example: a first metal layer (ohmic metal layer) in contact with the second nitride semiconductor layer 5, a second metal layer (main electrode metal layer) laminated on the first metal layer; a third metal layer (adhesive layer) laminated on the second metal layer; and a fourth metal layer (barrier metal layer) laminated on the third metal layer. The first metal layer is, for example, a Ti layer with a thickness in a range from about 10 nm to about 20 nm. The second metal layer is, for example, an Al layer with a thickness in a range from about 100 nm to about 300 nm. The third metal layer is, for example, a Ti layer with a thickness in a range from about 10 nm to about 20 nm. The fourth metal layer is, for example, a TiN layer with a thickness in a range from about 10 nm to about 50 nm.

In the nitride semiconductor device 1, a second nitride semiconductor layer 5 (electron supply layer) having a different band gap (concentration of aluminum) is formed on the first nitride semiconductor layer 4 (electron transportation layer) to form a heterojunction. Thereby, the two-dimensional electron gas 13 is formed in the first nitride semiconductor layer 4 proximal to the interface between the first nitride semiconductor layer 4 and the second nitride semiconductor layer 5, and an HEMT using the two-dimensional electron gas 13 as a channel is formed. The gate electrode 22 faces the second nitride semiconductor layer 5 with the third nitride semiconductor layer 21 and the etching stopper layer 6 interposed therebetween.

Below the gate electrode 22, by having the ionized acceptor contained in the third nitride semiconductor layer 21 composed of a p-type GaN layer, the energy level of the first nitride semiconductor layer 4 and the second nitride semiconductor layer 5 can be elevated. Thus, the energy level of the conduction band at the heterojunction interface between the first nitride semiconductor layer 4 and the second nitride semiconductor layer 5 is greater than the Fermi level. Therefore, no two-dimensional electron gas 13 caused by the spontaneous polarization of the first nitride semiconductor layer 4 and the second nitride semiconductor layer 5 or the piezoelectric polarization due to their lattice mismatch would be formed at a position directly below the gate electrode 22 (gate 20).

Therefore, when no bias is applied to the gate electrode 22 (at the time of zero bias), the channel of the two-dimensional electron gas 13 is blocked right under the gate electrode 22. In this way, a normally-off HEMT is realized. When an appropriate tum-on voltage (for example, 5 V) is applied to the gate electrode 22, a channel is induced in the first nitride semiconductor layer 4 right below the gate electrode 22, and the two-dimensional electronic gases 13 at two sides of the gate electrode 22 is connected. Thereby, conduction is established between the source and the drain.

In use, for example, between the source electrode 11 and the drain electrode 12, a positive specific voltage (for example, 50 V to 100 V) is applied on the side of the drain electrode 12. In this state, an off voltage (0 V) or an on voltage (5 V) is applied to the gate electrode 22 with the source electrode 11 as a reference potential (0 V).

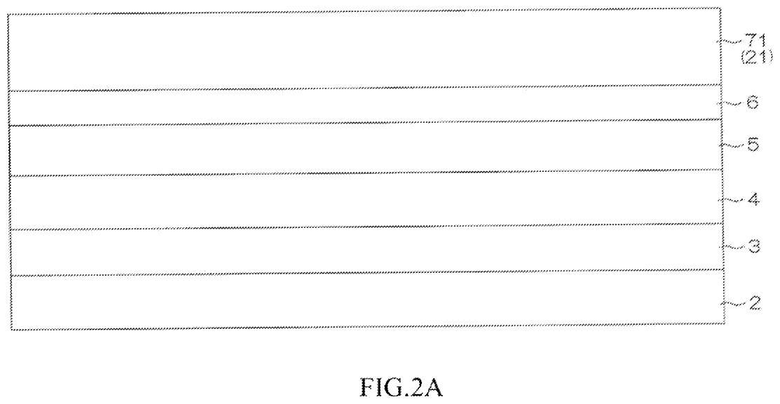

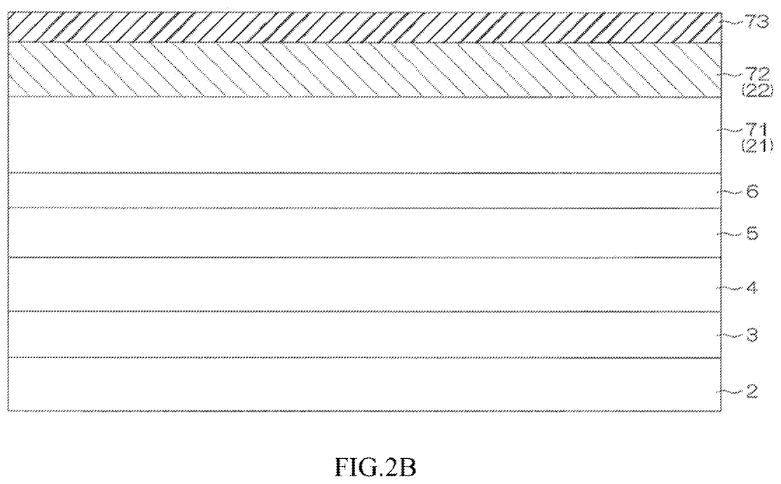

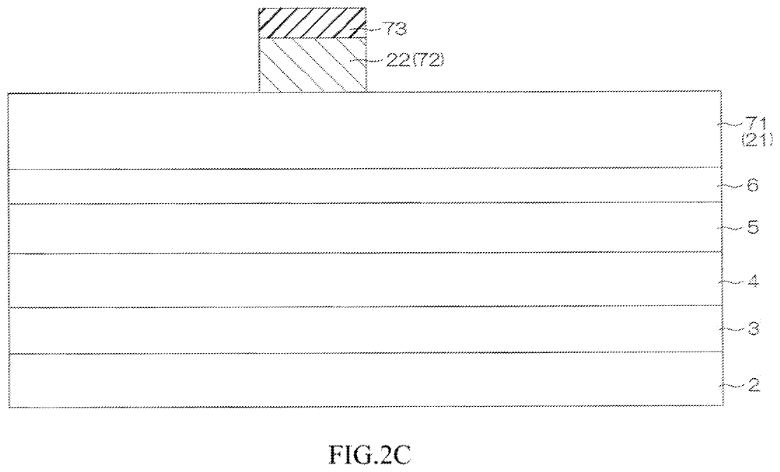

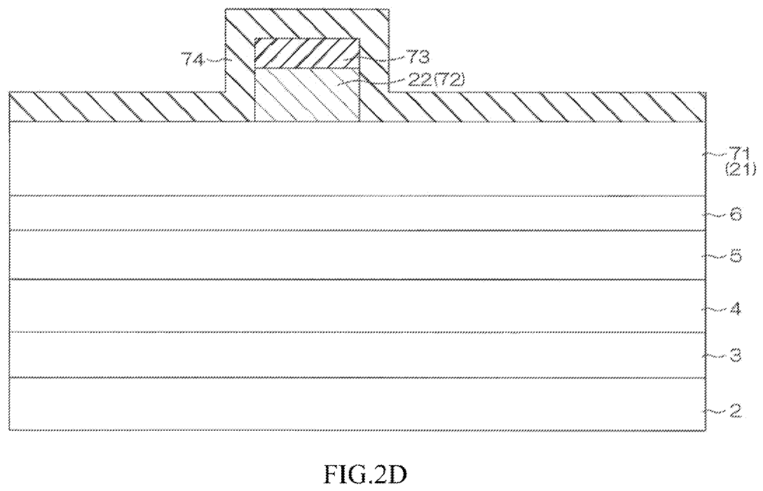

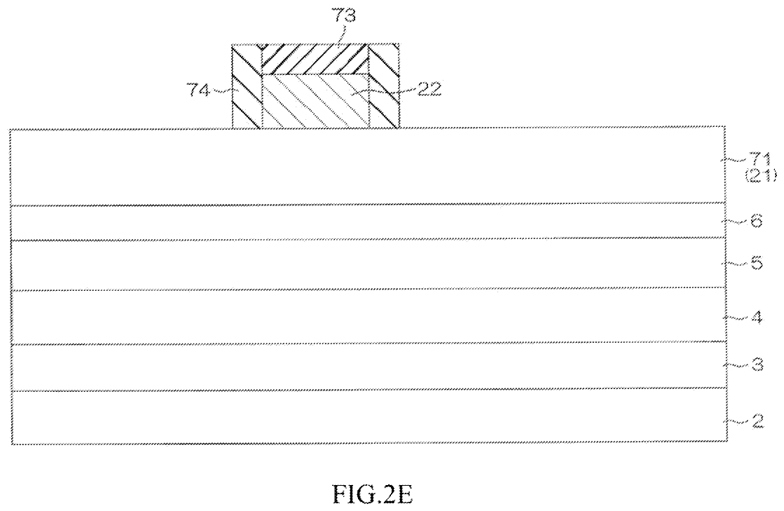

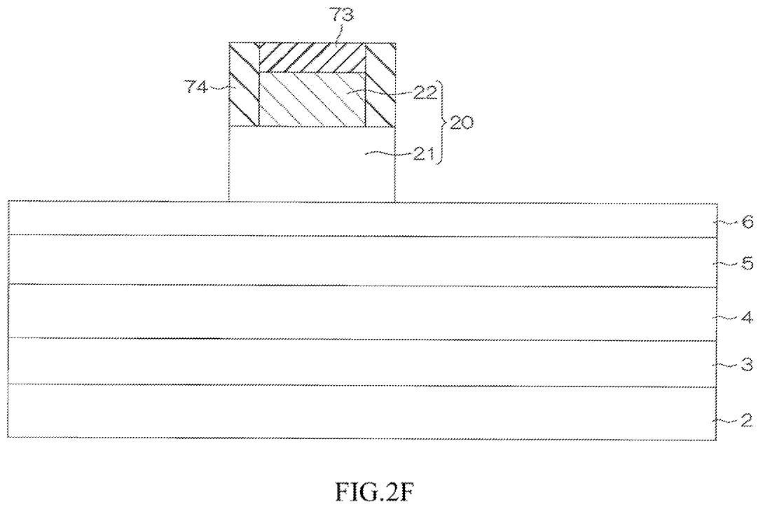

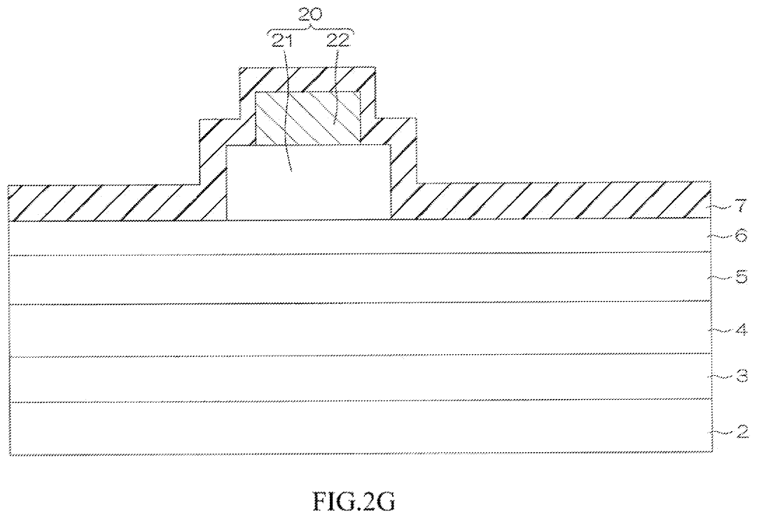

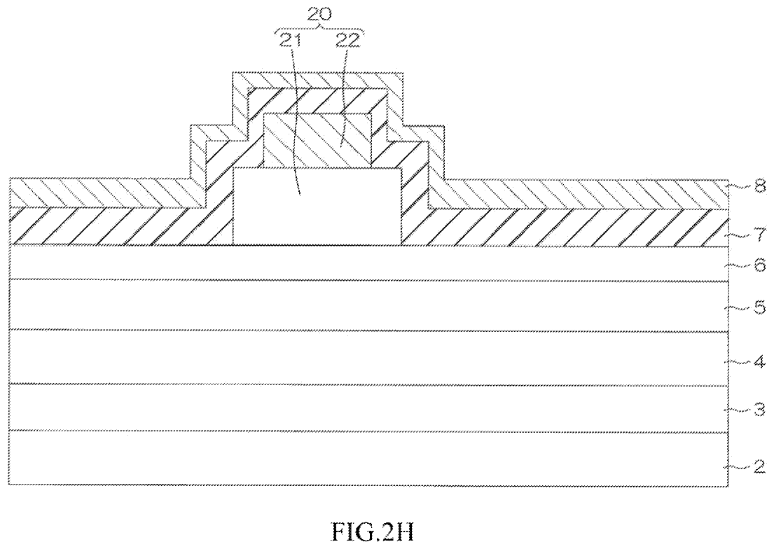

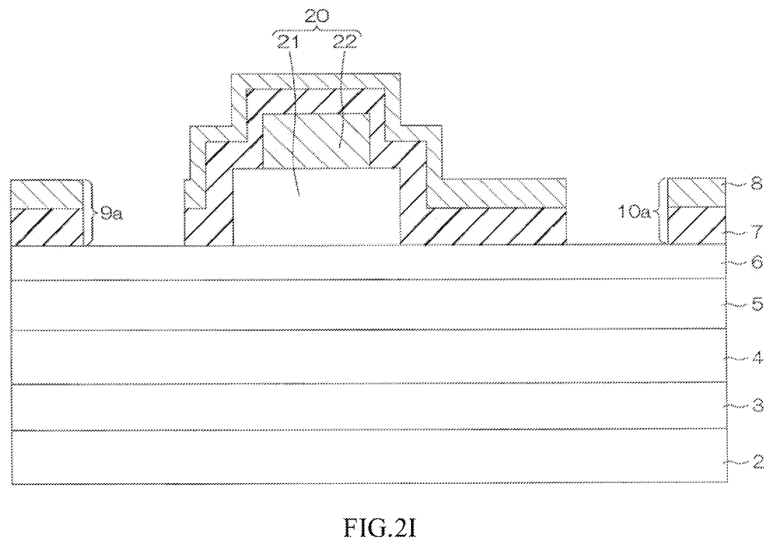

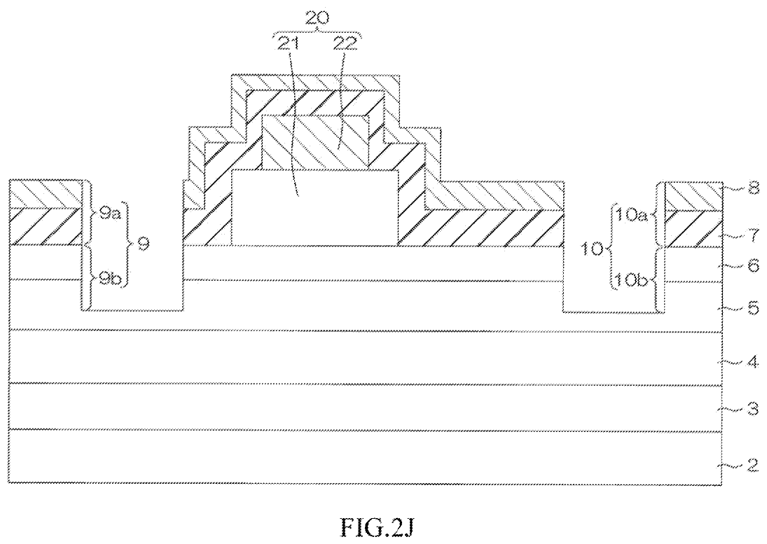

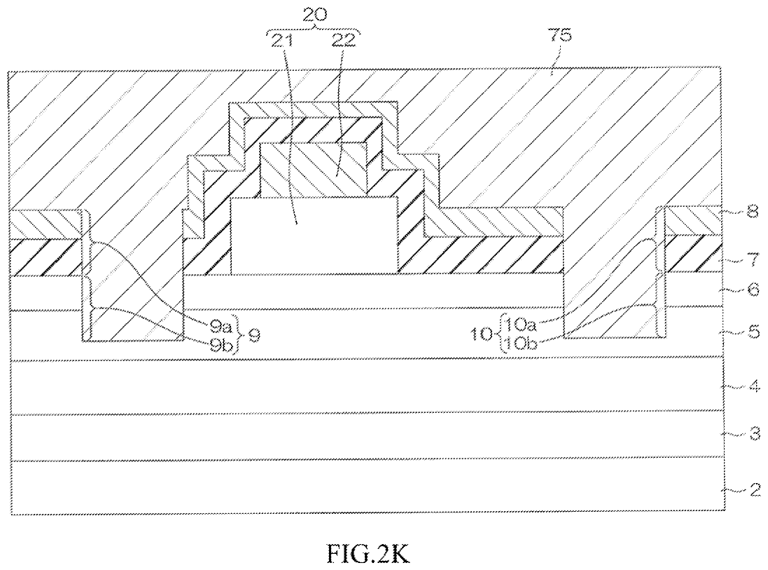

FIGS. 2A to 2K are cross-sectional views illustrating an example of the manufacturing operation of the nitride semiconductor device 1 and showing the cross-sectional structure at a plurality of stages in the manufacturing operation.

First, as shown in FIG. 2A, the buffer layer 3, the first nitride semiconductor layer (electron transportation layer) 4, the second nitride semiconductor layer (electron supply-layer) 5 and the etch stop layer 6 are epitaxially grown on the substrate 2 by using the MOCVD (Metal Organic Chemical Vapor Deposition) method. Further, the third semiconductor material film 71 as the material film of the third nitride semiconductor layer 21 is epitaxially grown on the etch stop layer 6 by using the MOCVD method.

Next, as shown in FIG. 2B, the gate electrode film 72 as the material film of the gate electrode 22 can be formed by using, for example, the sputtering operation to cover the entire exposed surface. Subsequently, the first silicon oxide film 73 is formed on the gate electrode film 72.

Next, as shown in FIG. 2C, for example, by using dry etch operation, the first silicon oxide film 73 is selectively removed, and a portion of the first silicon oxide film 73 is remained over a predetermined area of the gate electrode film 72 for forming gate electrode. Subsequently, the gate electrode film 72 is patterned by dry etching using the first silicon oxide film 73 as a mask. Thus, the gale electrode 22 is thereby formed.

Next, as shown in FIG. 2D, the second silicon oxide film 74 is formed to cover the entire exposed surface by, for example, the plasma chemical vapor deposition method (PECVD method).

Next, as shown in FIG. 2E, the second silicon oxide film 74 is etched back by dry etching, for example, so that the second silicon oxide film 74 covering the side surfaces of the gale electrode 22 and the first silicon oxide film 73 is formed.

Next, as shown in FIG. 2F, a dry etching operation is performed to pattern the third semiconductor material film 71 by using the first silicon oxide film 73 and the second silicon oxide film 74 as the mask. In this way, the third nitride semiconductor layer 21 having a ridge shape is formed. Thereby, the gate 20 including the third nitride semiconductor layer 21 with the ridge shape and the gate electrode 22 formed on the middle portion along width direction of the upper surface of the third nitride semiconductor layer 21 is formed.

Next, as shown in FIG. 2G, the first silicon oxide film 73 and the second silicon oxide film 74 are removed by wet etching. Subsequently, a passivation film 7 is formed so as to cover the entire exposed surface. For example, the passivation film 7 is made of SiN.

Next, as shown in FIG. 2H, a barrier metal film 8 is formed over the surface of the passivation film 7. For example, the barrier metal film 8 is made of TiN.

Next, as shown in FIGS. 2I and 2J, a source contact hole 9 and a drain contact hole 10 are formed in the laminated film of the second nitride semiconductor layer 5, the etch stop layer 6, the passivation film 7 and the barrier metal film 8. The source contact hole 9 and the drain contact hole 10 penetrate the barrier metal film 8, the passivation film 7 and the etch slop layer 6, and extend to the middle portion along the vertical direction of the second nitride semiconductor layer 5.

In the contact hole forming operation, firstly, as shown in FIG. 2I, the first portions 9a, 10a penetrating the laminated film of the passivation film 7 and the barrier metal film 8 along the vertical direction is formed by, for example, dry etching utilizing the fluorine (F)-containing gas.

Next, as shown in FIG. 2J, the second portions 9a and 10a respectively in connection with the first portions 9a and 10a, which penetrate the etch slop layer 6 and stop at the middle portion of the second nitride semiconductor layer 5 along the vertical direction, are formed in the laminated film of the second nitride semiconductor layer 5 and the etch stop layer 6 by, for example, dry etching utilizing the chlorine (Cl)-containing gas. Therefore, the source contact hole 9 including the first portion 9a and the second portion 9b, and the drain contact hole 10 including the first portion 10a and the second portion 10b are formed.

Next, as shown in FIG. 2K, a source-drain electrode film 75 is formed to cover the entire exposed surface.

Finally, the source-drain electrode film 75 and the barrier metal film 8 are patterned by photolithography and etching to form the source electrode 11 and the drain electrode 12, which are in contact with the second nitride semiconductor layer 5. In this way, a nitride semiconductor device 1 as shown in FIG. 1 is fabricated.

With regard to the nitride semiconductor device 1 of the first embodiment as shown in FIG. 1, since the film thickness of the third nitride semiconductor layer 21 is greater than 100 nm, the gate maximum rated voltage in the positive direction can be increased.

In addition, in the nitride semiconductor device 1 of the first embodiment, since the etch stop layer 6 is formed on the second nitride semiconductor layer 5, when the ridge-shaped third semiconductor material film 71 is patterned by etching (referring to FIG. 2F), it may help preventing the surface of the second nitride semiconductor layer 5 from being shaved off. In particular, in the nitride semiconductor device 1 of the first embodiment, it may be particularly effective since the removal amount of the second nitride semiconductor layer 5 may increase during patterning the third semiconductor material film 71 under the situation of the film thickness of the third nitride semiconductor layer 21 being relatively thick and without the etch slop layer 6.

On the other hand, under the situation of the etch stop layer 6 with a relatively large concentration of aluminum is formed on the second nitride semiconductor layer 5, the ohmic contact resistance of the source electrode 11 and the drain electrode 12 with respect to the two-dimensional electron gas 13 may increase due to the influence of the higher barrier. Alternatively stated, the on-resistance may increase.

With regard to the nitride semiconductor device I of the first embodiment, the source electrode 11 and the drain electrode 12 penetrates the etch stop layer 6 and extend to the middle portion of the second nitride semiconductor layer 5 along the vertical direction. Thereby, compared with a configuration in which the lower ends of the source elect rode 11 and the drain electrode 12 are in contact with the surface (upper surface) of the etch stop layer 6, the ohmic contact resistance of the source electrode 11 and the drain electrode 12 with respect to the two-dimensional electron gas 13 can be reduced. Therefore, the increasing of on-resistance may be mitigated.

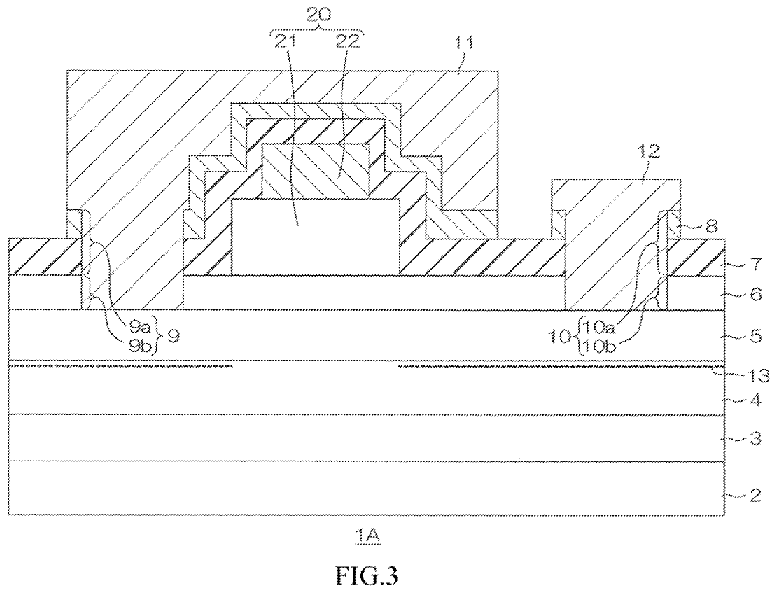

FIG. 3 is a cross-sectional view illustrating the structure of a nitride semiconductor device 1A according to a second embodiment of the present disclosure. In FIG. 3, the parts corresponding to the parts in FIG. 1 described above are denoted by the same reference numerals as in FIG. 1.

The difference between the nitride semiconductor device 1A of the second embodiment and the nitride semiconductor device 1 of the first embodiment resides in that the source contact hole 9 and the drain contact hole 10 do not extends into the second nitride semiconductor layer 5. Accordingly, the lower end positions of the end portions on the ohmic contact side of the source electrode 11 and the drain electrode 12 are different from those of the nitride semiconductor device 1 of the first embodiment. The other aspects are the same as the nitride semiconductor device 1 of the first embodiment.

With regard to the nitride semiconductor device 1A of the second embodiment, the source contact hole 9 includes: the first portion 9a penetrating the laminated film of the barrier metal film 8 and the passivation film 7 along the vertical direction; and the second portion 9b in connection with the first portion 9a, penetrates the etch stop layer 6 and stops at the surface of the second nitride semiconductor layer 5.

The end portion on the ohmic contact side of the source electrode 11 is embedded in the source contact hole 9. Therefore, the end portion on the ohmic contact side of the source electrode 11 penetrates the laminated film of the barrier metal film 8, the passivation film 7, and the etch stop layer 6 along the vertical direction, and is in contact with the surface of the second nitride semiconductor layer 5.

Similarly, the drain contact hole 10 includes: the first portion 10a that penetrates the laminated film of the barrier metal film 8 and the passivation film 7 along the vertical direction, and the second portion 10b that connects with the first portion 10a, which penetrates the etch stop layer 6 and stops at the surface of the second nitride semiconductor layer 5.

The portions of the first portions 9a and 10a that penetrate the passivation film 7 are equivalent to “the first hole” of the present disclosure corresponding to the second embodiment, and the second portions 9b and 10b are equivalent to “the second hole” of the present disclosure corresponding to the second embodiment.

The end portion on the ohmic contact side of the drain electrode 12 is embedded in the drain contact hole 10. Accordingly, the end portion on the ohmic contact side of the drain electrode 12 penetrates the laminated film of the barrier metal film 8, the passivation film 7, and the etch stop layer 6 along the vertical direction, and is in contact with the surface of the second nitride semiconductor layer 5.

Hereinafter, the manufacturing operation of the nitride semiconductor device 1A of the second embodiment will be described in FIGS. 4A to 4D, et cetera.

Firstly, the operation shown in FIGS. 2A to 2H are performed. In the operation of FIG. 2H, the barrier metal film 8 is formed on the surface of the passivation film 7, then as shown in FIGS. 4A to 4C the source contact hole 9 and the drain contact hole 10 are formed in the laminated film of the etch stop layer 6, the passivation film 7 and the barrier metal film 8. The source contact hole 9 and the drain contact hole 10 penetrate the harrier metal film 8, the passivation film 7 and the etch stop layer 6, and stop at the surface of the second nitride semiconductor layer 5.

In the contact hole fabrication operation, firstly, as shown in FIG. 4A, the first portions 9a, 10a penetrating the laminated film of the passivation film 7 and the barrier metal film 8 along the vertical direction is formed by, for example, dry etching utilizing the fluorine (F)-containing gas.

Next, as shown in FIG. 4B, the area facing the first portions 9a and 10a (the area below the first portions 9a and 10a) in the etch stop layer 6 is oxidized by dry treatment utilizing an oxygen-containing gas. In FIG. 4B, the oxidized area is indicated by dot hatching.

Subsequently, as shown in FIG. 4C, the oxidized area is removed by wet etching to form the second portions 9a and 10a that connect with the first portions 9a and 10a respectively and stop at the surface of the second nitride semiconductor layer 5. Thereby, the source contact hole 9 including the first portion 9a and the second portion 9b and the drain contact hole 10 including the first portion 10a and the second portion 10b are formed.

Next, as shown in FIG. 4D, the source-drain electrode film 75 is formed to cover the entire exposed surface.

Finally, the source-drain electrode film 75 and the barrier metal film 8 are patterned by photolithography and etching operation to form the source electrode 11 and the drain electrode 12 in ohmic contact with the second nitride semiconductor layer 5. Thereby, the nitride semiconductor device 1A as shown in FIG. 3 is fabricated.

With regard to the nitride semiconductor device IA of the second embodiment shown in FIG. 3, since the film thickness of the third nitride semiconductor layer 21 is greater than 100 nm, the gate maximum rated voltage in the positive direction may increase.

In addition, with regard to the nitride semiconductor device 1A of the second embodiment, since the etch slop layer 6 is formed over the second nitride semiconductor layer 5, during patterning the ridge-shaped third semiconductor material film 71 by etching (referring to FIG. 2F), it may help preventing the surface of the second nitride semiconductor layer 5 from being shaved off. In particular, with regard to the nitride semiconductor device 1A of the second embodiment, it may be particularly effective since the removal amount of the second nitride semiconductor layer 5 may increase during patterning the third semiconductor material film 71 under the situation of the film thickness of the third nitride semiconductor layer 21 being relatively thick and without the etch stop layer 6.

On the other hand, under the situation of the etch stop layer 6 with a relatively large concentration of aluminum is formed on the second nitride semiconductor layer 5, the ohmic contact resistance of the source electrode 11 and the drain electrode 12 with respect to the two-dimensional electron gas 13 may increase due to the influence of the higher barrier. Alternatively stated, the on-resistance may increase.

With regard to the nitride semiconductor device 1A of the second embodiment, the source electrode 11 and the drain electrode 12 penetrates the etch stop layer 6 to contact the surface of the second nitride semiconductor layer 5. Thus, compared with a configuration in which the lower ends of the source electrode 11 and the drain electrode 12 are in contact with the surface (upper surface) of the etch stop layer 6, the ohmic contact resistance of the source electrode 11 and the drain electrode 12 with respect to the two-dimensional electron gas 13 can be reduced. Therefore, the increasing of on-resistance may be mitigated.

FIG. 5 is a cross-sectional view illustrating the structure of a nitride semiconductor device 1B according to a third embodiment of the present disclosure. In FIG. 5, the parts corresponding to the parts in FIG. 1 described above are denoted by the same reference numerals as in FIG. 1.

The difference between the nitride semiconductor device 1B of the third embodiment and the nitride semiconductor device 1 of the first embodiment resides in that the etch stop layer 6 is not formed. Accordingly, the configuration of the end portions on the ohmic contact side of the source contact hole 9 and the drain contact hole 10 as well as the source electrode 11 and the drain electrode 12 is different from that of the nitride semiconductor device 1 of the first embodiment. Other aspects are identical to the nitride semiconductor device 1 of the first embodiment.

In the nitride semiconductor device 1B of the third embodiment, the source contact hole 9 includes: the first portion 9a penetrating the laminated film of the barrier metal film 8 and the passivation film 7 along the vertical direction, and the second portion 9b in connection with the first portion 9a and extending from the surface of the second nitride semiconductor layer 5 to the middle portion of the second nitride semiconductor layer 5 along the vertical direction.

The end portion on the ohmic contact side of the source electrode 11 is embedded in the source contact hole 9. Therefore, the end portion on the ohmic contact side of the source electrode 11 penetrates the laminated film of the barrier metal film 8 and the passivation film 7 along the vertical direction, and extends into the middle portion of the second nitride semiconductor layer 5 along the vertical direction. That is, the lower end of the end portion on the ohmic contact side of the source electrode 11 stops at the middle portion of the second nitride semiconductor layer 5 along the vertical direction.

Similarly, the drain contact hole 10 includes a first portion 10a that penetrates the laminated film of the barrier metal film 8 and the passivation film 7 along the vertical direction, and a second portion 10b that connects with the first portion 10a and extends from the surface of the second nitride semiconductor layer 5 to stop at the surface of the second nitride semiconductor layer 5.

The portions of the first portions 9a and 10a that penetrate the passivation film 7 is equivalent to “the first hole” of the present disclosure corresponding to the third embodiment, and the second portions 9a and 10a are equivalent to the “the second hole” of the present disclosure corresponding to the third embodiment.

The end portion on the ohmic contact side of the drain electrode 12 is embedded in the drain contact hole 10. Accordingly, the end portion on the ohmic contact side of the drain electrode 12 penetrates the laminated film of the barrier metal film 8 and the passivation film 7 along the vertical direction and extends into the middle portion of the second nitride semiconductor layer 5 along the vertical direction. That is, the lower end of the end portion on the ohmic contact side of the drain electrode 12 stops at the middle portion of the second nitride semiconductor layer 5 along the vertical direction.

Moreover, the distance d between the bottom surfaces of the second portions 9a and 10a (the lower ends of the source electrode 11 and the drain electrode 12) and the lower surface of the second nitride semiconductor layer 5 is preferably more than ⅕ and less than ½ of the film thickness t of the second nitride semiconductor layer 5. The criticality is similar to the first embodiment.

The manufacturing method of the nitride semiconductor device 1B of the third embodiment is the substantially identical the manufacturing method of the nitride semiconductor device 1 of the first embodiment, except the difference resides in that the etch stop layer 6 is not formed on the second nitride semiconductor layer 5. Therefore, the operation diagrams of the manufacturing method of the nitride semiconductor device 1B of the third embodiment can be referred to FIG. 2A to FIG. 2K, but without having the etch stop layer 6.

With regard to the nitride semiconductor device 1B of the third embodiment shown in FIG. 5, since the film thickness of the third nitride semiconductor layer 21 is greater than 100 nm, the gate maximum rated voltage in the positive direction may be increased.

In the nitride semiconductor device 1B of the third embodiment, the source electrode 11 and the drain electrode 12 extends to the middle portion of the second nitride semiconductor layer 5 along the vertical direction from the surface of the second nitride semiconductor layer 5. Thus, compared with a configuration in which the lower ends of the source electrode 11 and the drain electrode 12 are in contact with the surface of the second nitride semiconductor layer 5, the ohmic contact resistance of the source electrode 11 and the drain electrode 12 with respect to the two-dimensional electron gas 13 can be reduced. Therefore, the increasing of on-resistance may be mitigated.

The first to third embodiments of the present disclosure have been described above, but the present disclosure can be further implemented in other embodiments. In the above embodiments, the barrier metal film 8 is formed on the passivation film 7, but in some other alternative embodiments, the barrier metal film 8 may not be formed on the passivation film 7.

In the above-mentioned embodiments, silicon or the like is exemplified as an example of the material of the substrate 2. Further, any substrate material such as a sapphire substrate or a QST substrate can also be applied in some other embodiments.

In addition, various design changes can be implemented within the scope of the matters staled in the claims.

What is claimed is:

1. A nitride semiconductor device, comprising:
a first nitride semiconductor layer, configured as an electron transportation layer;
a second nitride semiconductor layer, over the first nitride semiconductor layer and configured as an electron supply layer, wherein the second nitride semiconductor layer has a bandgap greater than a bandgap of the first nitride semiconductor layer;
an etch stop layer over the second nitride semiconductor layer, comprising a nitride semiconductor material having a bandgap greater than that the bandgap of the second nitride semiconductor layer;
a gate, over the etch stop layer; and
a source electrode and a drain electrode over the etch stop layer, wherein the gate is between the source electrode and the drain electrode,
wherein the gate comprises:
a third nitride semiconductor layer over the second nitride semiconductor layer, wherein the third nitride semiconductor layer is ridge-shaped and comprises acceptor impurity; and
a gate electrode over the third nitride semiconductor layer, wherein lower portions of the source electrode and the drain electrode penetrate the etch stop layer and extend into a middle portion of the second semiconductor layer along a vertical direction. 2. The nitride semiconductor device of claim 1, wherein a distance between a lower surface of the second nitride semiconductor layer and the lower portions of the source electrode and the drain electrode is in a range between one fifth of a thickness of the second nitride semiconductor layer to a half of the thickness of the second nitride semiconductor layer.

3. A nitride semiconductor device, comprising:
a first nitride semiconductor layer, configured as an electron transportation layer;
a second nitride semiconductor layer, over the first nitride semiconductor layer and configured as an electron supply layer, wherein the second nitride semiconductor layer has a bandgap greater than a bandgap of the first nitride semiconductor layer;
an etch stop layer over the second nitride semiconductor layer, comprising a nitride semiconductor material having a bandgap greater than the second nitride semiconductor layer:
a gate, over the etch stop layer; and
a source electrode and a drain electrode over the etch stop layer, wherein the gate is between the source electrode and the drain electrode, wherein the gate comprises:
a third nitride semiconductor layer over the second nitride semiconductor layer, wherein the third nitride semiconductor layer is ridge-shaped and comprises acceptor impurity; and
a gate electrode over the third nitride semiconductor layer, wherein lower portions of the source electrode and the drain electrode penetrate the etch stop layer along a vertical direction and is in direct contact with an upper surface of the second semiconductor layer.

4. The nitride semiconductor device of claim 3, wherein a thickness of the etch stop layer is in a range from 0.5 nm to 2 nm.

5. The nitride semiconductor device of claim 3, wherein the etch stop layer and the second nitride semiconductor layer comprises aluminum, a concentration of aluminum in the etch stop layer is greater than a concentration of aluminum in the second nitride semiconductor layer.

6. The nitride semiconductor device of claim 5, wherein the concentration of aluminum in the etch stop layer is greater than 80%.

7. The nitride semiconductor device of claim 6, wherein the concentration of aluminum in the second nitride semiconductor layer is less than 25%.

8. The nitride semiconductor device of claim 5, a difference between the concentration of aluminum in the etch stop layer and the concentration of aluminum in the second nitride semiconductor layer is greater than 50%.

9. The nitride semiconductor device of claim 3, wherein the etch stop layer in made of AlGaN or AlN.

10. A nitride semiconductor device, comprising:
a first nitride semiconductor layer, configured as an electron transportation layer;
a second nitride semiconductor layer, over the first nitride semiconductor layer and configured as an electron supply layer, wherein the second nitride semiconductor layer has a bandgap greater than a bandgap of the first nitride semiconductor layer;
a gate, over the second nitride semiconductor layer; and
a source electrode and a drain electrode over the second nitride semiconductor layer, wherein the gate is between the source electrode and the drain electrode,
wherein the gate comprises:
a third nitride semiconductor layer over the second nitride semiconductor layer, wherein the third nitride semiconductor layer is ridge-shaped and comprises acceptor impurity; and
a gate electrode over the third nitride semiconductor layer, wherein lower portions of the source electrode and the drain electrode extend from an upper surface of the second semiconductor layer into in a middle portion of the second semiconductor layer along a vertical direction.

11. The nitride semiconductor device of claim 10, wherein a distance between a lower surface of the second nitride semiconductor layer and the lower portions of the source electrode and the drain electrode is in a range between one fifth of a thickness of the second nitride semiconductor layer to a half of the thickness of the second nitride semiconductor layer.

12. The nitride semiconductor device of claim 10, wherein a thickness of the third nitride semiconductor layer is greater than 110 nm. 13. The nitride semiconductor device of claim 10, wherein:
the first nitride semiconductor layer is made of GaN;
the second nitride semiconductor layer is made of AlGaN; and
the third nitride semiconductor layer is made of AlGaN.

14. The nitride semiconductor device of claim 10, wherein the acceptor impurity is Magnesium or Zinc.

15. A method for forming a nitride semiconductor device, comprising:
forming a first nitride semiconductor layer configured as an electron transportation layer over a substrate;
forming a second nitride semiconductor layer configured as an electron supply layer over the substrate subsequent to forming the first nitride semiconductor layer;
forming an etch stop layer over the substrate subsequent to forming the second nitride semiconductor layer;
forming a semiconductor gate material film made of a nitride semiconductor comprising acceptor impurity over the substrate after forming the etch stop layer;
forming a gate electrode film over the semiconductor gate material film;
selectively etching the gate electrode film to form a gate electrode over the semiconductor gate material film;
selectively etching the semiconductor gate material film to form a semiconductor gate layer over the etch stop layer, wherein a semiconductor gate layer is formed above the gate electrode;
forming a passivation film over the etch stop layer, wherein the passivation film covers an exposed surface of the second nitride semiconductor layer, the semiconductor gate layer, and an exposed surface of the gate electrode;
forming contact holes in a film stack of the passivation layer, the etch stop layer, and the second nitride semiconductor layer, comprising:
forming a source contact hole and a drain contact hole penetrating the passivation film and the etch stop layer along a vertical direction and stopping at a middle portion of the second nitride semiconductor layer; and
forming a source electrode and a drain electrode respectively traversing the source contact hole and the drain contact hole, wherein the source electrode and the drain electrode are in direct contact with the second nitride semiconductor layer.

16. The method of claim 15, wherein forming contact holes comprising:
performing a dry etching operation by using fluorine-containing gas to form a first hole penetrating the passivation layer; and
performing a dry etching operation by using chlorine-containing gas to form a second hole connecting to the first hole, penetrating the etch stop layer and stopping at the middle portion of the second nitride semiconductor layer.

17. A method for forming a nitride semiconductor device, comprising:
forming a first nitride semiconductor layer configured as an electron transportation layer over a substrate;
forming a second nitride semiconductor layer configured as an electron supply layer over the substrate subsequent to forming the first nitride semiconductor layer;
forming an etch stop layer over the substrate subsequent to forming the second nitride semiconductor layer;
forming a semiconductor gate material film made of a nitride semiconductor comprising acceptor impurity over the substrate after forming the etch stop layer;
forming a gate electrode film over the semiconductor gate material film;
selectively etching the gate electrode film to form a gate electrode over the semiconductor gate material film;
selectively etching the semiconductor gate material film to form a semiconductor gate layer over the etch stop layer, wherein a semiconductor gate layer is formed above the gate electrode;
forming a passivation film over the second nitride semiconductor layer, wherein the passivation film covers an exposed surface of the second nitride semiconductor layer, the semiconductor gale layer, and an exposed surface of the gate electrode;
forming contact holes in a film stack of the passivation layer and the etch stop layer, comprising:
forming a source contact hole and a drain contact hole penetrating the passivation film and the etch stop layer along a vertical direction and stopping at an upper surface of the second nitride semiconductor layer; and
forming a source electrode and a drain electrode respectively traversing the source contact hole and the drain contact hole, wherein the source electrode and the drain electrode are in direct contact with the upper surface of the second nitride semiconductor layer.

18. The method of claim 17, wherein forming contact holes comprising:
performing a dry etching operation by using fluorine-containing gas to form a first hole penetrating the passivation layer;
performing a dry treatment by using oxygen-containing gas to oxidize a region in the passivation layer proximal to the first hole; and
performing a wet etching operation to remove the region oxidized by the dry treatment, thereby forming a second hole connecting to the first hole, penetrating the etch stop layer and slopping at an upper surface of the second nitride semiconductor layer.

19. A method for forming a nitride semiconductor device, comprising:
forming a first nitride semiconductor layer configured as an electron transportation layer over a substrate;
forming a second nitride semiconductor layer configured as an electron supply layer over the substrate subsequent to forming the first nitride semiconductor layer;
forming a semiconductor gate material film made of a nitride semiconductor comprising acceptor impurity over the substrate after forming the second nitride semiconductor layer;
forming a gate electrode film over the semiconductor gate material film;
selectively etching the gate electrode film to form a gate electrode over the semiconductor gate material film;
selectively etching the semiconductor gate material film to form a semiconductor gate layer over the second nitride semiconductor layer, wherein a semiconductor gate layer is formed above the gate electrode;
forming a passivation film over the second nitride semiconductor layer, wherein the passivation film covers an exposed surface of the second nitride semiconductor layer, the semiconductor gate layer, and an exposed surface of the gate electrode;
forming contact holes in a film stack of the passivation layer and the second nitride semiconductor layer, comprising:
forming a source contact hole and a drain contact hole penetrating the passivation film along a vertical direction and stopping at a middle portion of the second nitride semiconductor layer; and
forming a source electrode and a drain electrode respectively traversing the source contact hole and the drain contact hole, wherein the source electrode and the drain electrode are in direct contact with the second nitride semiconductor layer.

20. The method of claim 19, wherein forming contact holes comprising:
performing a dry etching operation by using fluorine-containing gas to form a first hole penetrating the passivation layer; and
performing a dry etching operation by using chlorine-containing gas to form a second hole connecting to the first hole, penetrating the etch stop layer and stopping at the middle portion of the second nitride semiconductor layer.
